(19) United States
(12) Patent Application Publication
(10) Pub. No.: US 2006/0244502 A1
(43) Pub. Date: Nov. 2, 2006

(54) Sense amplifier-based flip-flop circuit

(75) Inventor: Min-Su Kim, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/364,003

(22) Filed: Mar. 1, 2006

(30) Foreign Application Priority Data
Apr. 27, 2005 (KR) 10-2005-0035158

(51) Int. Cl. H03K 3/356

(52) U.S. Cl. 327/208; 327/57

(57) ABSTRACT

The sense amplifier-based flip-flop circuit includes a pulse generator and a sense amplifier. The pulse generator is configured to generate a signal pulse in response to one of a first transition and a second transition of a clock signal. The sense amplifier is configured to sense differential input signals in response to the signal pulse and maintain the sensed differential input signals until a subsequent signal pulse is received.

### FIELD OF THE INVENTION

The present invention relates to a digital logic circuit. In particular, the present invention relates to a sense amplifier-based flip-flop circuit.

### BACK GROUND OF THE INVENTION

A sense amplifier-based flip-flop circuit (hereinafter, referred to as a “SAFF circuit”) has been used widely due to differential characteristics, fast operating speed, and low power consumption. This SAFF circuit is implemented by various approaches within digital circuits such as microprocessors, digital signal processing units, and the like. The SAFF circuit acts as a receiver of high-speed input/output interfaces such as RAMBUS or DDR synchronous dynamic random access memories or as a phase detector of a digital delay locked loop.

Exemplary SAFF circuits are disclosed in U.S. Pat. No. 6,107,853 entitled “SENSE AMPLIFIER BASED FLIP-FLOP”, U.S. Pat. No. 6,414,529 entitled “LATCH AND D-TYPE FLIP-FLOP”, U.S. Pat. No. 6,633,188 entitled “SENSE AMPLIFIER-BASED FLIP-FLOP WITH ASYNCHRONOUS SET AND RESET”, and U.S. Pat. No. 6,717,448 entitled “DATA OUTPUT METHOD AND DATA OUTPUT CIRCUIT FOR APPLYING REDUCED PRECHARGE LEVEL”.

SAFF circuits according to the prior art are illustrated in FIGS. 1 and 2. SAFF circuits illustrated in FIGS. 1 and 2 are disclosed in the above-mentioned '853 patent. As illustrated in FIGS. 1 and 2, a SAFF circuit may include two stages. A first stage is a master stage and includes a sense amplifier for sensing and amplifying a small signal. A second stage is a slave stage and includes an RS-latch. The SAFF circuit is configured to latch an input signal at a master stage during a first interval (e.g., a high-level interval) of a clock signal CLK and to maintain the latched signal during a second interval (e.g., a low-level interval) of the clock signal CLK. Since the SAFF circuit includes a master stage and a slave stage, the circuit is relatively large. For this reason, in case of digital circuits needing a number of flip-flops, the SAFF circuit in FIGS. 1 and 2 restricts decreasing the size of digital circuits.

Another SAFF circuit is illustrated in FIG. 3. The SAFF circuit in FIG. 3 is disclosed in IEE Electronics Letters (Vol. 36, No 6, pp. 498-500) entitled “A CMOS SENSE AMPLIFIER-BASED FLIP-FLOP WITH TWO N-Cˆ2MOS OUTPUT LATCHES”. A sense amplifier of SAFF circuit in FIG. 3 is identical to that in FIGS. 1 and 2, while its latch consists of an N-Cˆ2MOS latch instead of the RS-latch in FIGS. 1 and 2. When a clock signal CLK is at a low level, /S and /R nodes are all precharged with supply voltage Vdd. If an input D goes high at a rising edge of the clock signal CLK, the /S node is changed from Vdd to a ground voltage and the /R node is maintained at Vdd. Accordingly, Q is pulled up to Vdd and /Q is pulled down to a ground voltage. On the other hand, if an input D goes low at a rising edge of the clock signal CLK, the /R node is changed from Vdd to a ground voltage and the /S node is maintained at Vdd. Accordingly, /Q is pulled up to Vdd and Q is pulled down to a ground voltage. When the clock signal CLK is at a low level, transistors P5, P6, N7, and N9 are turned off. This forces Q and /Q to float. At this time, Q and /Q values are maintained by corresponding latches I1-I2 and I3-I4, respectively.

But, one problem of the SAFF circuit in FIG. 3 is that it is not suitable for low-power digital devices since excessive short circuit current is caused at Q and /Q when the input signal D does not change.

### SUMMARY OF THE INVENTION

Some embodiments of the invention provide a low-power sense amplifier-based flip-flop circuit.

Other embodiments of the invention provide a sense amplifier-based flip-flop circuit capable of reducing a chip size.

Still other embodiments of the invention provide a sense amplifier-based flip-flop circuit capable of improving an operating speed.

In accordance with at least one aspect of the present invention, a flip-flop circuit is provided which comprises a pulse generator for generating a signal pulse in response to one of a first transition and a second transition of a clock signal; and a sense amplifier for sensing differential input signals to generate sensed differential input signals in response to the signal pulse and for maintaining the sensed differential input signals until receipt of a subsequent signal pulse.

Pursuant to this embodiment, the pulse generator may generate the signal pulse in synchronization with a low-to-high transition of the clock signal.

Pursuant to this embodiment, the pulse generator may generate the signal pulse in synchronization with a high-to-low transition of the clock signal.

Pursuant to this embodiment, a pulse width of the signal pulse may be maintained constant regardless of a frequency variation of the clock signal.

Pursuant to this embodiment, the signal pulse may transition from high-to-low and then from low-to-high; and the sense amplifier is configured to sense the differential input signal at a rising edge of the signal pulse.

Pursuant to this embodiment, the sense amplifier comprises a pulse input terminal for receiving the signal pulse; first and second input terminals for receiving the differential input signals, respectively; and first and second output terminals for outputting the sensed differential input signals, respectively.

Pursuant to this embodiment, the sense amplifier may perform a precharge operation from a falling edge of the signal pulse to the rising edge of the signal pulse so that the first and second output terminals are precharged with a voltage.

Pursuant to this embodiment, the flip-flop circuit further comprises first and second inverters connected to the first and second output terminals, respectively.

Pursuant to this embodiment, the flip-flop circuit further comprises a PMOS transistor connected between the first and second output terminals and controlled by the pulse signal.

In accordance with another aspect of the present invention, a flip-flop circuit is provided which comprises a pulse generator for generating a signal pulse in response to one of a first transition and a second transition of a clock signal; a sense amplifier for sensing differential input signals to generate sensed differential input signal in response to the signal pulse and maintaining the sensed differential input signals until receipt of a subsequent signal pulse; and a buffer for buffering the sensed differential input signals from the sense amplifier.

Pursuant to this embodiment, the sense amplifier comprises a pulse input terminal for receiving the pulse signal; first and second input terminals for receiving the differential input signals, respectively; and first and second output terminals for outputting the sensed differential input signals, respectively.

Pursuant to this embodiment, the pulse generator may generate the signal pulse in synchronization with a low-to-high transition of the clock signal.

Pursuant to this embodiment, the pulse generator may generate the signal pulse in synchronization with a high-to-low transition of the clock signal.

Pursuant to this embodiment, a pulse width of the signal pulse may be maintained constantly regardless of a frequency variation of the clock signal.

Pursuant to this embodiment, the sense amplifier may perform a precharge operation from a falling edge of the signal pulse to the rising edge of the signal pulse so that the first and second output terminals are precharged with a voltage.

Pursuant to this embodiment, the buffer comprises a first inverter connected to the first output terminal; and a second inverter connected to the second output terminal.

Pursuant to this embodiment, the buffer further comprises a first PMOS transistor having a current path formed between a power supply voltage and a first buffer output terminal and a gate connected to the second output terminal; a first NMOS transistor having a current path formed between the first buffer output terminal and a ground voltage and a gate connected to an output of the first inverter; a second PMOS transistor having a current path formed between the power supply voltage and a second buffer output terminal and a gate connected to the first output terminal; and a second NMOS transistor having a current path formed between the second buffer output terminal and the ground voltage and a gate connected to an output of the second inverter.

Pursuant to this embodiment, the buffer further comprises a third NMOS transistor having a current path formed between the first NMOS transistor and the ground voltage and a gate connected to receive a first control input signal; a third PMOS transistor having a current path formed between the power supply voltage and the first buffer output terminal and a gate connected to receive the first control input signal; a fourth NMOS transistor having a current path formed between the second NMOS transistor and the ground voltage and a gate connected to receive a second control input signal; and a fourth PMOS transistor having a current path formed between the power supply voltage and the second buffer output terminal and a gate connected to receive the second control input signal.

Pursuant to this embodiment, the buffer further comprises a third PMOS transistor having a current path formed between the power supply voltage and the first PMOS transistor and a gate connected to receive a first control input signal; a third NMOS transistor having a current path formed between the first buffer output terminal and the ground voltage and a gate connected to receive the first control input signal; a fourth NMOS transistor having a current path formed between the second NMOS transistor and the ground voltage and a gate connected to receive a second control input signal; and a fourth PMOS transistor having a current path formed between the power supply voltage and the second buffer output terminal and a gate connected to receive the second control input signal.

Pursuant to this embodiment, the flip-flop circuit may further comprise a PMOS transistor connected between the first and second output terminals and controlled by the signal pulse.

Pursuant to this embodiment, the buffer comprises a first PMOS transistor having a current path formed between a power supply voltage and a first buffer output terminal and a gate connected to a second output terminal; a first NMOS transistor having a drain connected to the first buffer output terminal, a source, and a drain connected to receive the signal pulse; a second NMOS transistor having a drain connected to the source of the first NMOS transistor, a source grounded, and a gate connected to the second output terminal; a second PMOS transistor having a current path formed between the power supply voltage and a second buffer output terminal and a gate connected to the first output terminal; a third NMOS transistor having a drain connected to the second buffer output terminal, a source, and a gate connected to receive the signal pulse; and a fourth NMOS transistor having a drain connected to the source of the third NMOS transistor, a source grounded, and a gate connected to the first output terminal.

In accordance with another embodiment of the present invention, an operating method of a sense amplifier-based flip-flop circuit comprises generating a signal pulse in response to one of a first transition and a second transition of a clock signal; precharging outputs of the sense amplifier in response to the signal pulse; sensing differential input signals in response to the signal pulse; and maintaining the sensed differential input signals until a subsequent signal pulse.

Pursuant to this embodiment, the signal pulse may be generated in synchronization with a low-to-high transition of the clock signal.

Pursuant to this embodiment, the signal pulse may be generated in synchronization with a high-to-low transition of the clock signal.

Pursuant to this embodiment, a pulse width of the signal pulse is maintained constant regardless of a frequency variation of the clock signal.

Pursuant to this embodiment, the signal pulse may transition from high-to-low and then from low-to-high; the precharging step may precharge the sense amplifier in response to a falling edge of the signal pulse; and the sensing step may sense the differential input signals in response to a rising edge of the pulse signal.

Pursuant to this embodiment, the sensed differential input signals may be buffered.

### BRIEF DESCRIPTION OF THE DRAWINGS

A more complete appreciation of the present invention, and many of the attendant advantages thereof, will become readily apparent as the same becomes better understood by reference to the following detailed description when considered in conjuction with the accompanying drawings in which like reference symbols indicate like components, wherein:

FIGS. 1 to 3 are circuit diagrams showing sense amplifier-based flip-flop circuits according to the prior art;

FIG. 4 is a block diagram showing a sense amplifier-based flip-flop circuit according to one embodiment of the present inventions;

FIGS. 5A to 5D are circuit diagrams showing the pulse generator illustrated in FIG. 4 according to embodiments of the present invention;

FIG. 6 is a waveform diagram of an output signal from respective pulse generators illustrated in FIGS. 5A and 5C;

FIGS. 7A to 7C are circuit diagrams showing the sense amplifier illustrated in FIG. 4 according to embodiments of the present invention;

FIG. 8 is a timing diagram for describing an operation of a sense amplifier-based flip-flop illustrated in FIG. 4;

FIG. 9 is a block diagram showing a sense amplifier-based flip-flop circuit according to another embodiment of the present invention;

FIGS. 10A and 10B are circuit diagrams showing the sense amplifier illustrated in FIG. 9 according to embodiments of the present invention;

FIG. 11 is a timing diagram for describing an operation of the sense amplifier-based flip-flop illustrated in FIG. 9;

FIGS. 12A and 12B are circuit diagrams showing the sense amplifier-based flip-flop circuits illustrated in FIG. 9 including a NAND logic function according to embodiments of the present invention;

FIGS. 13A and 13B are circuit diagrams showing the sense amplifier-based flip-flop circuits illustrated in FIG. 9 including a NOR logic function according to embodiments of the present invention;

FIGS. 14A and 14B are circuit diagrams showing the sense amplifier-based flip-flop circuits illustrated in FIG. 9 including NAND and NOR logic functions according to embodiments of the present invention;

FIGS. 15A and 15B are circuit diagrams showing a tri-state buffer of the sense amplifier-based flip-flop circuit illustrated in FIG. 9 according to embodiments of the present invention; and

FIG. 16 is a block diagram showing a sense amplifier-based flip-flop circuit according to another embodiment of the present invention.

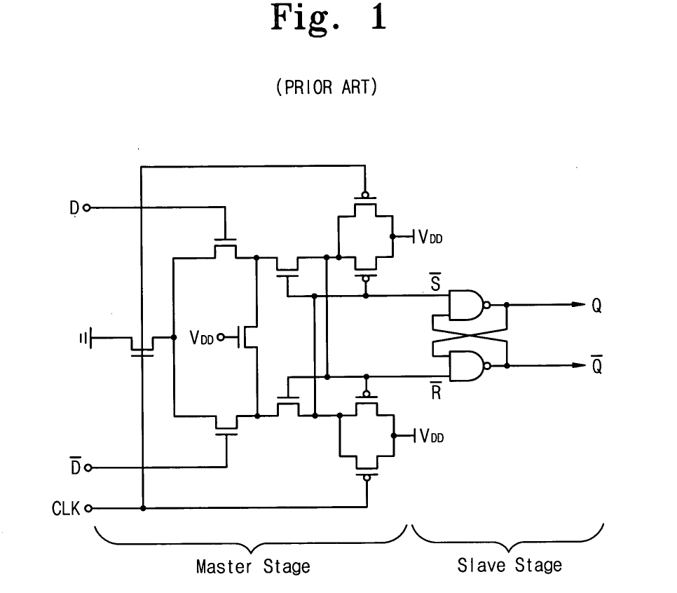

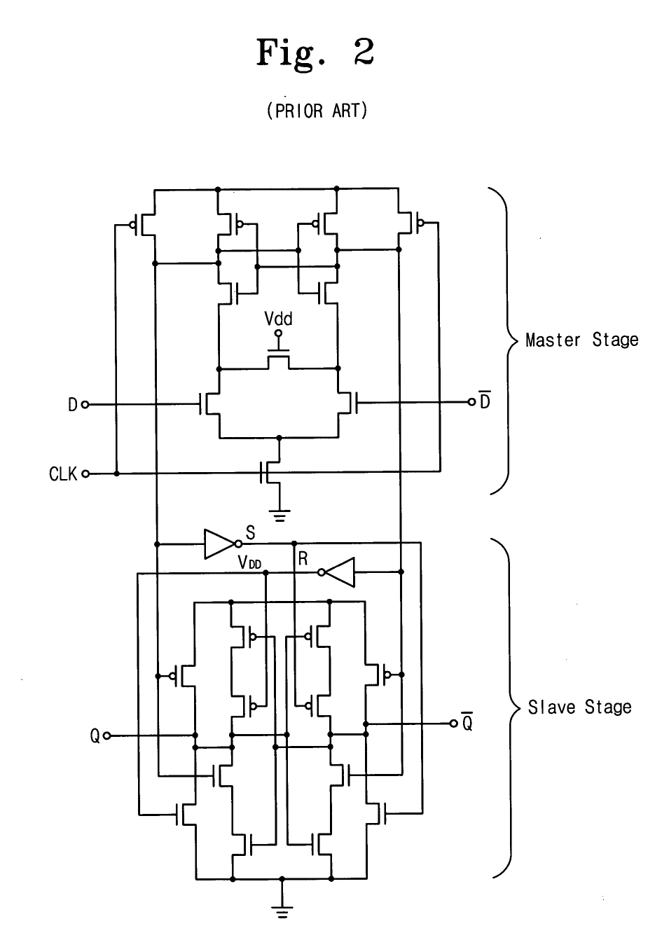

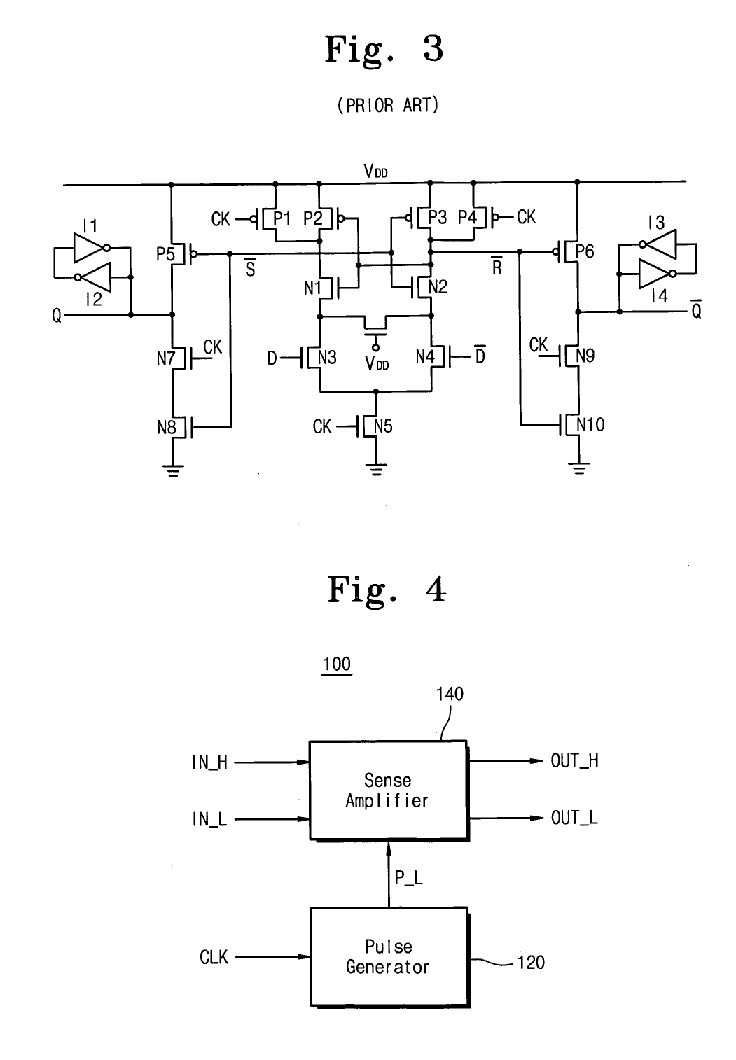

### DETAILED DESCRIPTION OF THE EXAMPLE EMBODIMENTS

The example embodiments of the invention will be more fully described with reference to the attached drawings.

FIG. 4 shows a sense amplifier-based flip-flop circuit according to a first embodiment of the present invention.

Referring to FIG. 4, SAFF circuit 100 comprises a pulse generator 120 and a sense amplifier 140. The pulse generator 120 receives a clock signal CLK and generates an active low pulse signal P_L in response to a rising edge of the received clock signal CLK. Alternatively, the pulse generator 120 generates an active low pulse signal P_L in response to a falling edge of the received clock signal CLK. The sense amplifier 140 senses differential input signals IN_H and IN_L in response to the active low pulse signal P_L. The sense amplifier 140 outputs the sensed differential input signals as differential output signals OUT_H and OUT_L. For example, the sense amplifier 140 senses differential input signals IN_H and IN_L at a rising edge of the active low pulse signal P_L and maintains the sensed differential input signals during one cycle of the clock signal CLK (or, during a time interval from a rising edge of an active low pulse signal generated at an nth clock cycle until a falling edge of an active low pulse signal generated at a (n+1)th clock cycle).

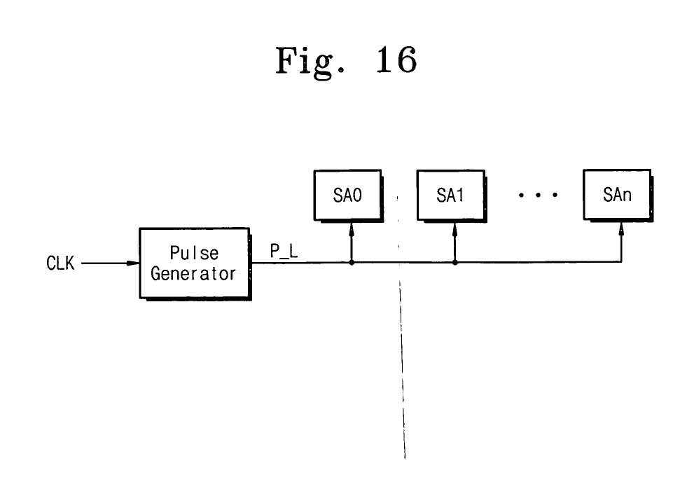

As illustrated in FIG. 4, the SAFF circuit 100 only consists of the pulse generator 120 and the sense amplifier 140. This enables the chip size and power dissipation of digital circuits to be reduced. In addition, the pulse generator 120 of the SAFF circuit 100 may be used in common for a plurality of sense amplifiers as illustrated in FIG. 16. That is, the pulse generator 120 may be dedicated to one sense amplifier, or may be used in common for a plurality of sense amplifiers. Considering this fact, the SAFF circuit 100 according to the first embodiment of the invention makes it easy to reduce the chip size of digital circuits. Further, since data latched/sensed only by a sense amplifier is maintained during one clock cycle, it is possible to eliminate a delay time usually caused by latch That is, the operating speed of the SAFF circuit is improved.

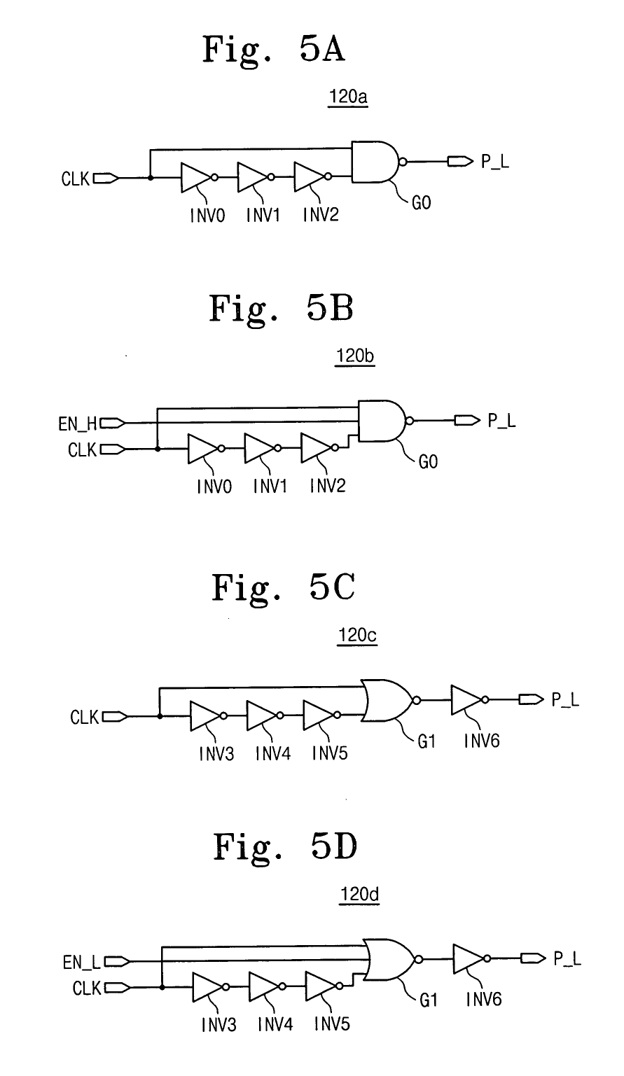

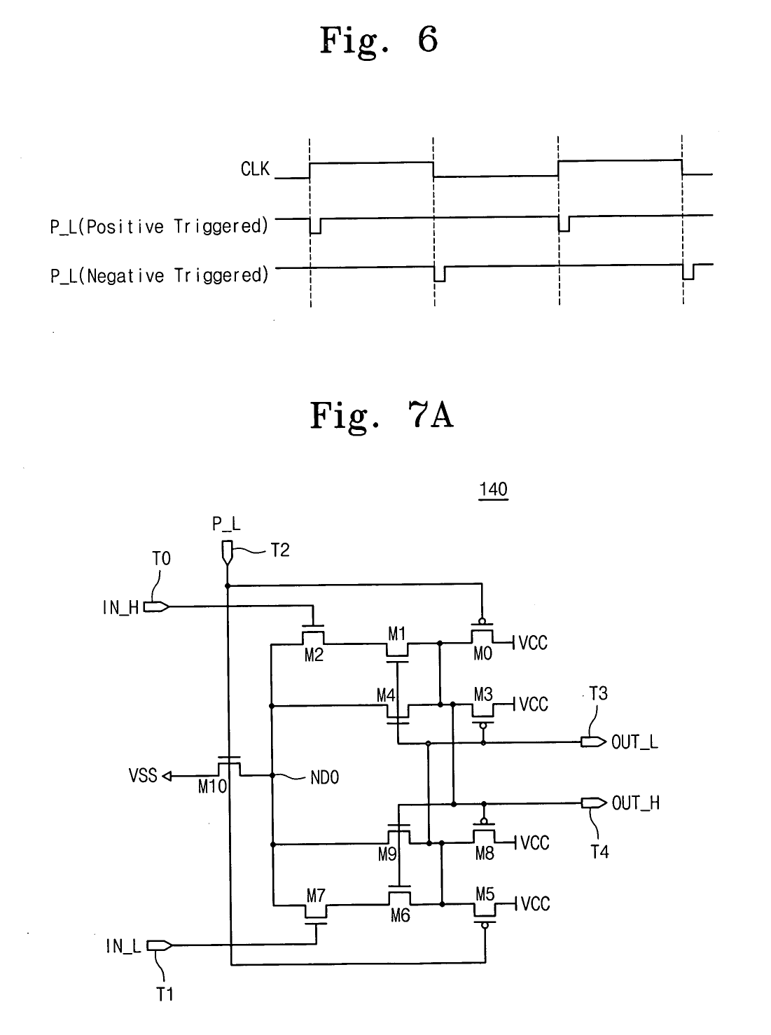

FIGS. 5A to 5D are circuit diagrams showing embodiments of the pulse generator illustrated in FIG. 4, and FIG. 6 is a waveform diagram of an output signal from the respective pulse generators illustrated in FIGS. 5A and 5C.

Referring to FIG. 5A, a pulse generator 120a includes three inverters INV0, INV1, and INV2 connected in series to one input of a NAND gate G0. The other input of the NAND gate G0 and the inverter INV0 receive the clock signal CLK. With this configuration, as illustrated in FIG. 6, the pulse generator 120a is triggered at a rising edge of a clock signal CLK. When the clock signal CLK is at a low level, an active low pulse signal P_L goes high. If the clock signal CLK transitions from a low level to a high level, as illustrated in FIG. 6, the active low pulse signal P_L transitions from a high level to a low level. That is, the active low pulse signal P_L is activated. The active low pulse signal P_L transitions from a low level to a high level after a delay time of the inverters INV0 to INV2. That is, the active low pulse signal P_L is deactivated. An inactive or deactivated state of the active low pulse signal P_L is maintained until a low-to-high transition of the clock signal CLK of a next cycle. Although a period (or a frequency) of the clock signal CLK is varied, a pulse width of the active low pulse signal P_L, which is determined by the inverters INV0 to INV2, is maintained constant.

A pulse generator 120b illustrated in FIG. 5B is identical to that in FIG. 5A except that an enable signal EN_H is also applied to the NAND gate G0. When the enable signal EN_H is at a high level, an active low pulse signal P_L is generated in synchronization with a clock signal CLK. When the enable signal EN_H is at a low level, no active low pulse signal P_L is generated. Accordingly, it is possible to reduce the power dissipated by a SAFF circuit when operation of the SAFF circuit is unnecessary using the enable signal EN_H.

A pulse generator 120c illustrated in FIG. 5C includes three inverters INV3, INV4, and INV5 connected in series to an input of a NOR gate G1. The other input of the NOR gate G1 and the inverter INV3 receive the clock signal CLK. An inverter INV6 is connected to the output of the NOR gate G1. With this construction, the pulse generator 120c generates the active low pulse signal P_L in synchronization with a falling edge of a clock signal CLK. That is, as illustrated in FIG. 6, the pulse generator 120c is triggered at a falling edge of the clock signal CLK. The pulse generator 120c operates the same as that in FIG. 5A except for the above-described difference, and description thereof is thus omitted for the sake of brevity.

A pulse generator 120d illustrated in FIG. 5D is identical to that in FIG. 5C except that an enable signal EN_L is also applied to the NOR gate G1. When the enable signal EN_L is at a high level, an active low pulse signal P_L is generated in synchronization with a clock signal CLK. When the enable signal EN_L is at a low level, no active low pulse signal P_L is generated. Accordingly, it is possible to reduce the power dissipated by the SAFF circuit when operation of the SAFF circuit is unnecessary by using the enable signal EN_L.

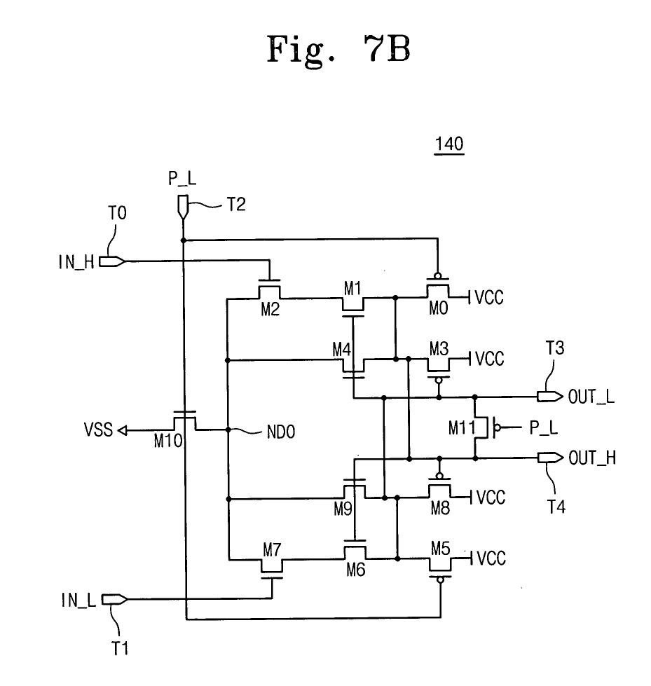

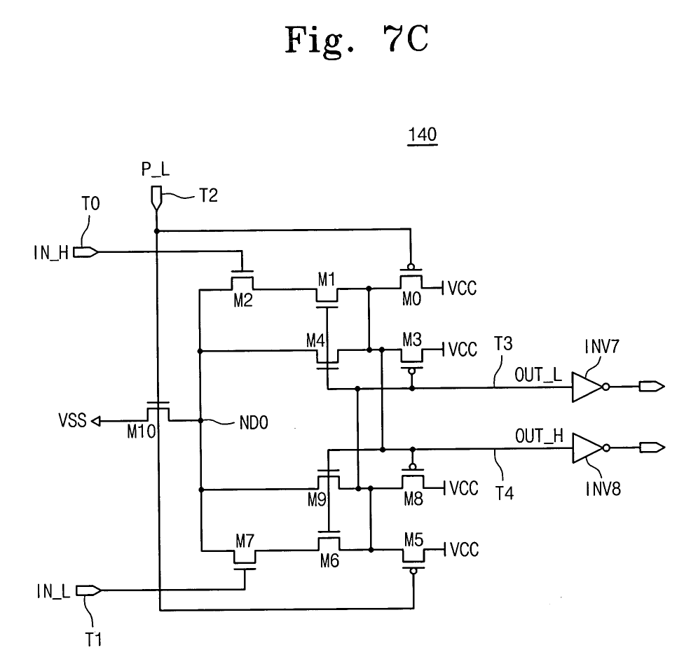

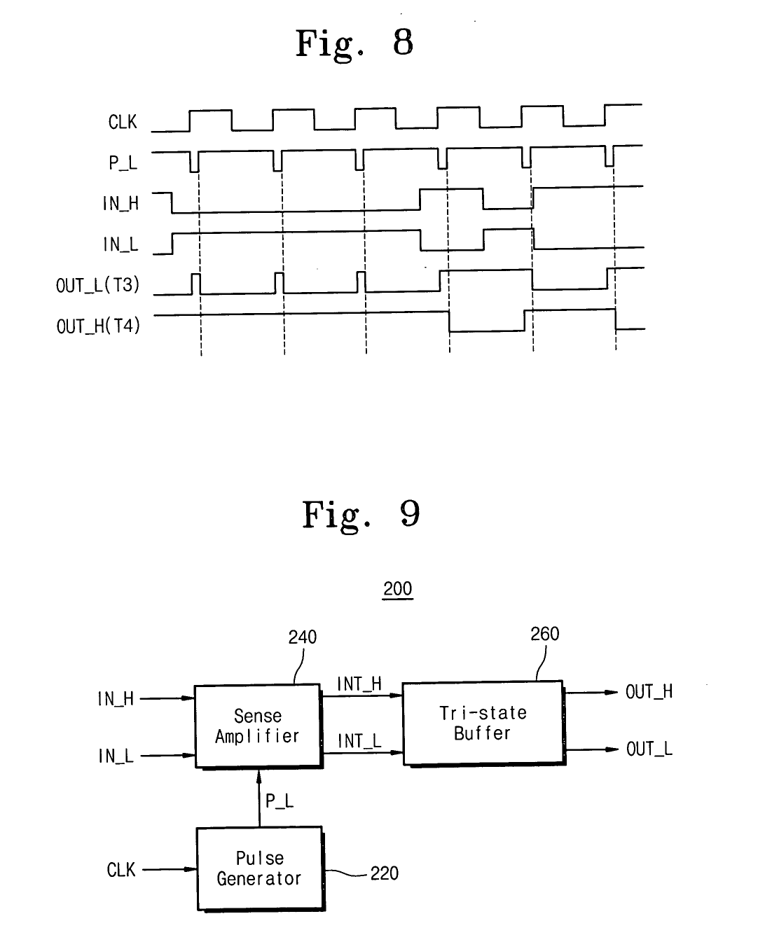

FIG. 7A shows a circuit diagram of the sense amplifier illustrated in FIG. 4 according to an embodiment of the present invention.

Referring to FIG. 7A, the sense amplifier 140 has input terminals T0 and T1 for receiving differential input signals IN_H and IN_L, a pulse terminal T2 for receiving an active low pulse signal P_L, and output terminals T3 and T4 for outputting differential output signals OUT_H and OUT_L. The sense amplifier 140 includes a plurality of NMOS transistors M1, M2, M4, M6, M7, M9, and M10 and a plurality of PMOS transistors M0, M3, M5, and M8. The PMOS transistor M0 whose gate is connected to the T2 terminal has a source connected to a power supply voltage VCC and a drain connected to the T4 terminal. The NMOS transistor M1 has a drain connected to the T4 terminal, a source, and a gate connected to the T3 terminal. The NMOS transistor M2 whose gate is connected to the T0 terminal has a drain connected to the source of the NMOS transistor M1 and a source connected to a node ND0. The PMOS transistor M3 has a source connected to the power supply voltage VCC, a drain connected to the T4 terminal, and a gate connected to the T3 terminal. The NMOS transistor M4 has a drain connected to the T4 terminal, a source connected to the ND0 node, and a gate connected to the T3 terminal. The NMOS transistor M10 whose gate is connected to the T2 terminal has a drain connected to the ND0 node and a source that is grounded.

The PMOS transistor M5 whose gate is connected to the T2 terminal has a source connected to the power supply voltage VCC and a drain connected to the T3 terminal. The NMOS transistor M6 has a drain connected to the T3 terminal, a source, and a gate connected to the T4 terminal. The NMOS transistor M7 whose gate is connected to the T1 terminal has a drain connected to the source of the NMOS transistor M6 and a source connected to the ND0 node. The PMOS transistor M8 has a source connected to the power supply voltage VCC, a drain connected to the T3 terminal, and a gate connected to the T4 terminal. The NMOS transistor M9 has a drain connected to the T3 terminal, a source connected to the ND0 node, and a gate connected to the T4 terminal.

FIG. 8 shows a timing diagram of a sense amplifier-based flip-flop circuit according to the embodiment illustrated in FIG. 7A. Below, an operation of the sense amplifier-based flip-flop circuit according to the first embodiment will be more fully described with reference to the accompanying drawings.

Once a clock signal CLK transitions from a low level to a high level, a pulse generator 120 activates an active low pulse signal P_L low. PMOS transistors M0 and M5 in a sense amplifier 140 are turned on by the activated pulse signal P_L. T3 and T4 terminals in the sense amplifier 140 are precharged with a power supply voltage VCC through the turned-on transistors M0 and M5. At this time, transistors M3, M8 and M10 in the sense amplifier 140 are turned off, while transistors M1, M4, M6, and M9 are turned on. This state is a precharge state of the sense amplifier 140. Since the NMOS transistor M10 is turned off at the precharge state, potential variations of the T0 and T1 terminals in the sense amplifier 140 do not affect this precharge state.

Then, as the active low pulse signal P_L transitions from a low level to a high level, the PMOS transistors M0 and M5 are turned off and the NMOS transistor M10 is turned on. If the active low pulse signal P_L goes high in synchronization with a low-to-high transition of the clock signal CLK, the sense amplifier 140 senses and amplifies differential input signals IN_H and IN_L, which are applied to the T0 and T1 terminals, in response to a low-to-high transition of the active low pulse signal P_L. This will be more fully described below.

Since the differential input signals IN_H and IN_L have a low level and a high level respectively, the NMOS transistor M2 is turned off and the NMOS transistor M7 is turned on. This makes a voltage of the T3 terminal discharged through the NMOS transistors M6, M7, M9, and M10. That is, a power supply voltage VCC of the T3 terminal is lowered to a ground voltage. At this time, the PMOS transistor M3 is turned on and the T4 terminal retains a precharged voltage that is, a power supply voltage VCC. As a result, the differential output signals OUT_H and OUT_L go to a high level and a low level, respectively. The differential output signals OUT_H and OUT_L are maintained by the sense amplifier 140 during a high-level interval of the active low pulse signal P_L.

As a clock signal CLK of a next cycle transitions from a low level to a high level, the active low pulse signal P_L transitions from a high level to a low level. This makes the T3 and T4 terminals of the sense amplifier 140 be precharged at a power supply voltage VCC in the same manner as described above. Afterward, precharge and sense/amplification operations are carried out the same as described above, and description thereof is thus omitted.

As understood from the above description, sensed input signals IN_H and IN_L are kept by the sense amplifier 140 during one cycle of the clock signal CLK. This means that a SAFF circuit for securing data during one clock cycle is constituted only by the pulse generator 120 and the sense amplifier 140. Accordingly, the chip size and power consumption are reduced and an operating speed is improved.

The sense amplifier 140 illustrated in FIG. 7B is identical to that in FIG. 7A except that a PMOS transistor M11 controlled by an active low pulse signal P_L is added. Accordingly, except for this difference, the sense amplifier of FIG. 7A will not be described in detail for the sake of brevity. As described above, the T3 and T4 terminals are precharged at a power supply voltage VCC when the active low pulse signal P_L is at a low level. During a low-level interval of the active low pulse signal P_L, the T3 and T4 terminals have a power supply voltage VCC and a ground voltage VSS (or a ground voltage and a power supply voltage) based on differential input signals IN_H and IN_L. Accordingly, the PMOS transistor M11 is used to reduce a time needed for precharging the T3 and T4 terminals from a ground voltage VSS to a power supply voltage VCC during the precharge operation. Alternatively, the PMOS transistor M11 is used to speed up a precharge operation for the T3 and T4 terminals. This occurs because when the active low pulse signal P_L is low during the precharge operation, the PMOS transistor M11 electrically connects the T3 and T4 terminals.

The sense amplifier 140 illustrated in FIG. 7C is identical to that in FIG. 7A except that inverters INV7 and INV8 are connected to output terminals T3 and T4, respectively. Accordingly, except for this difference, the sense amplifier of FIG. 7A will not be described in detail for the sake of brevity. As will be appreciated, in this embodiment the inverter INV7 inverts the level of the OUT_L differential output signal, and the inverter INV8 inverts the level of the OUT_H differential output signal.

FIG. 9 shows a block diagram of a sense amplifier-based flip-flop circuit according to a second embodiment of the present invention.

Referring to FIG. 9, a SAFF circuit 200 includes the pulse generator 120, a sense amplifier 140, and a tri-state buffer 260. As discussed above, the pulse generator 120 receives a clock signal CLK and generates an active low pulse signal P_L in response to a rising edge of the received clock signal CLK. Alternatively, the pulse generator 120 generates an active low pulse signal P_L in response to a falling edge of the received clock signal CLK. The sense amplifier 140 senses differential input signals IN_H and IN_L in response to the active low pulse signal P_L and outputs the sensed differential input signals INT_H and INT_L. For example, the sense amplifier 140 senses differential input signals IN_H and IN_L at a rising edge of the active low pulse signal P_L and maintains the sensed differential input signals INT_H and INT_L during one cycle of the clock signal CLK (or, during a time interval from a rising edge of an active low pulse signal generated at an nth clock cycle until a falling edge of an active low pulse signal generated at a (n+1)th clock cycle). The tri-state buffer 260 buffers the sensed signals INT_H and INT_L and outputs differential output signals OUT_H and OUT_L.

As illustrated in FIG. 9, the SAFF circuit 200 only consists of the pulse generator 120, the sense amplifier 140, and the tri-state buffer 260. This enables the chip size and power dissipation of digital circuits to be reduced. In addition, the pulse generator 120 of the SAFF circuit 200 may be used in common for a plurality of sense amplifiers as illustrated in FIG. 16. That is, the pulse generator 120 may be dedicated to one sense amplifier, or may be used in common for a plurality of sense amplifiers. Considering this fact, the SAFF circuit 200 according to the second embodiment of the invention makes it easy to reduce the chip size of digital circuits.

Because the pulse generator 120, various embodiments thereof, the sense amplifier 140, and various embodiments thereof were discussed in detail above, those descriptions will not be repeated for the sake of brevity.

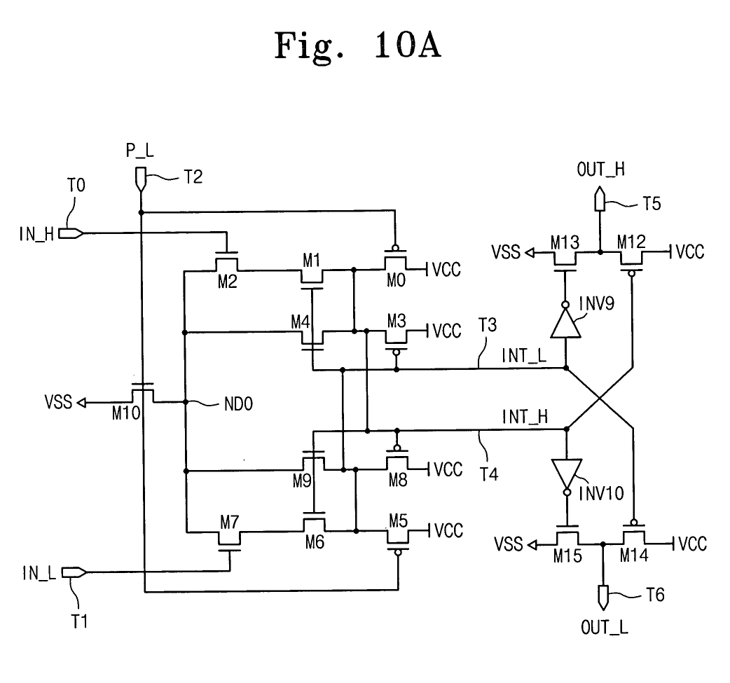

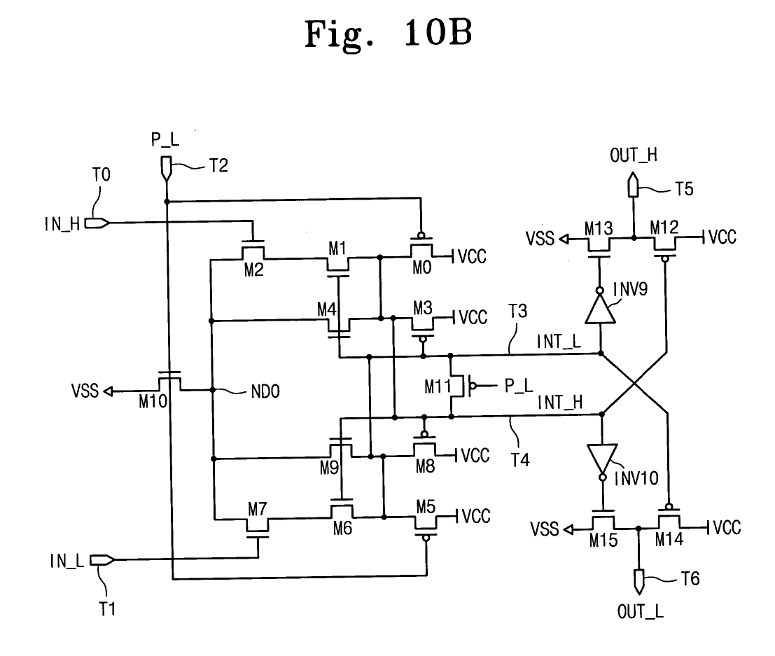

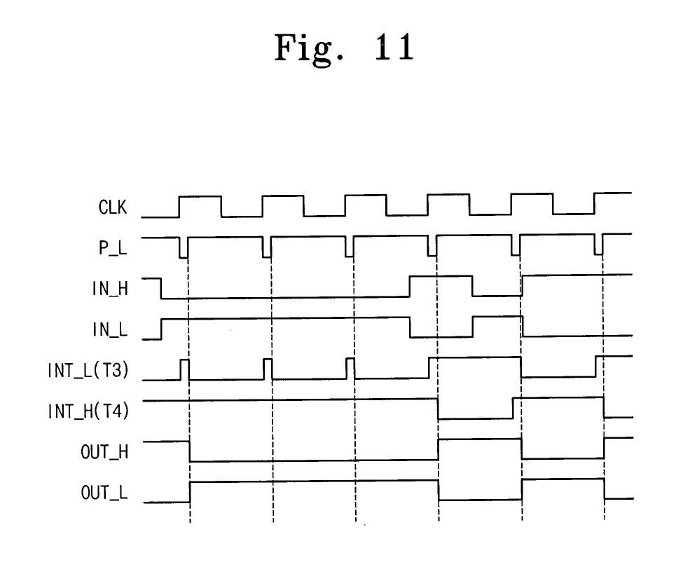

FIG. 10A shows a circuit diagram of a sense amplifier and a tri-state buffer illustrated in FIG. 9. Because the sense amplifier 140 illustrated in FIG. 10A is identical to that in FIG. 7A, constituent elements of the sense amplifier 140 in FIG. 10A are marked by the same numerals as illustrated in FIG. 7A, and description thereof is thus omitted.

Referring to FIG. 10A, a tri-state buffer 260 comprises inverters INV9 and INV10, PMOS transistors M12 ad M14, and NMOS transistors M13 and M15. The PMOS transistor M12 is connected between a power supply voltage VCC and a T5 terminal, and has a gate connected to receive a sensed signal INT_H (OUT_H in FIG. 7A). The NMOS transistor M13 is connected between the T5 terminal and a ground voltage VSS, and has a gate connected to receive a sensed signal (OUT_L in FIG. 7A) INT_L via the inverter INV9. The PMOS transistor M14 is connected between a power supply voltage VCC and a T6 terminal, and has a gate connected to receive the sensed signal INT_L. The NMOS transistor M15 is connected between the T6 terminal and a ground voltage VSS, and has a gate connected to receive the sensed signal INT_H via the inverter INV10.

FIG. 11 shows a timing diagram of the sense amplifier-based flip-flop circuit according to the second embodiment shown in FIGS. 9-10A. Below, an operation of the sense amplifier-based flip-flop circuit according to the second embodiment will be more fully described with reference to the accompanying drawings.

Once a clock signal CLK transitions from a low level to a high level, the pulse generator 120 activates an active low pulse signal P_L low. PMOS transistors M0 and M5 in the sense amplifier 140 are turned on in response to the activated pulse signal P_L. The T3 and T4 terminals in the sense amplifier 140 are precharged with a power supply voltage VCC through the turned-on transistors M0 and M5. This enables output terminals T5 and T6 to retain previous states. At this time, transistors M3, M8 and M10 in the sense amplifier 140 are turned off, while transistors M1, M4, M6, and M9 are turned on. This state becomes a precharge state of the sense amplifier 140. Since the NMOS transistor. M10 is turned off at the precharge state, potential variations of the T0 and T1 terminals in the sense amplifier 140 do not affect this precharge state.

Then, as the active low pulse signal P_L transitions from a low level to a high level in synchronization with a low-to-high transition of the clock signal CLK, the PMOS transistors M0 and M5 are turned off and the NMOS transistor M10 is turned on. If the active low pulse signal P_L goes high, the sense amplifier 140 senses and amplifies differential input signals IN_H and IN_L, which are applied to the T0 and T1 terminals, in response to a low-to-high transition of the active low pulse signal P_L. This will be more fully described below.

Since the differential input signals IN_H and IN_L have a low level and a high level respectively, the NMOS transistor M2 is turned off and the NMOS transistor M7 is turned on. This makes a voltage of the T3 terminal discharged through the NMOS transistors M6, M7, M9, and M10. The power supply voltage VCC at the T3 terminal is lowered to a ground voltage VSS. At this time, the PMOS transistor M3 is turned on and the T4 terminal retains a precharged voltage—the power supply voltage VCC. As a result, sensed signals INT_H and INT_L go to a high level and a low level, respectively. At this time, NMOS and PMOS transistors M13 and M14 in a tri-state buffer 260 are turned on, and NMOS and PMOS transistors M15 and M12 are turned off. Accordingly, differential output signals OUT_H and OUT_L go to a low level and a high level, respectively. As illustrated in FIG. 11, the differential output signals OUT_H and OUT_L are maintained by the sense amplifier 140 during a high-level interval of the active low pulse signal P_L.

As a clock signal CLK of a next cycle again transitions from a low level to a high level, the active low pulse signal P_L transitions from a high level to a low level. This forces the T3 and T4 terminals of the sense amplifier 140 to precharged at a power supply voltage VCC in the same manner as described above. Afterwards, precharge and sense/amplification operations are carried out the same as described above, and description thereof is thus omitted.

As understood from the above description, sensed signals INT_H and INT_L are maintained by the sense amplifier 140 during one cycle of the clock signal CLK. This means that the SAFF circuit for securing data during one clock cycle is constituted only by the pulse generator 120, the sense amplifier 140, and the tri-state buffer 260. Accordingly, the chip size and power consumption of the SAFF circuit are reduced.

The sense amplifier 140 in FIG. 10B is identical to that in FIG. 10A except that a PMOS transistor M11 is added which is controlled by an active low pulse signal P_L. A detailed description thereof is omitted as this embodiment of the sense amplifier 140 was described above with respect to FIG. 7B. As described above, the T3 and T4 terminals are precharged at a power supply voltage VCC when an active low pulse signal P_L is at a low level. During a low-level interval of the active low pulse signal P_L, the T3 and T4 terminals have a power supply voltage VCC and a ground voltage VSS (or a ground voltage and a power supply voltage) based on differential input signals IN_H and IN_L. As discussed above, the PMOS transistor M16 is used to speed up a precharge operation for the T3/T4 terminals.

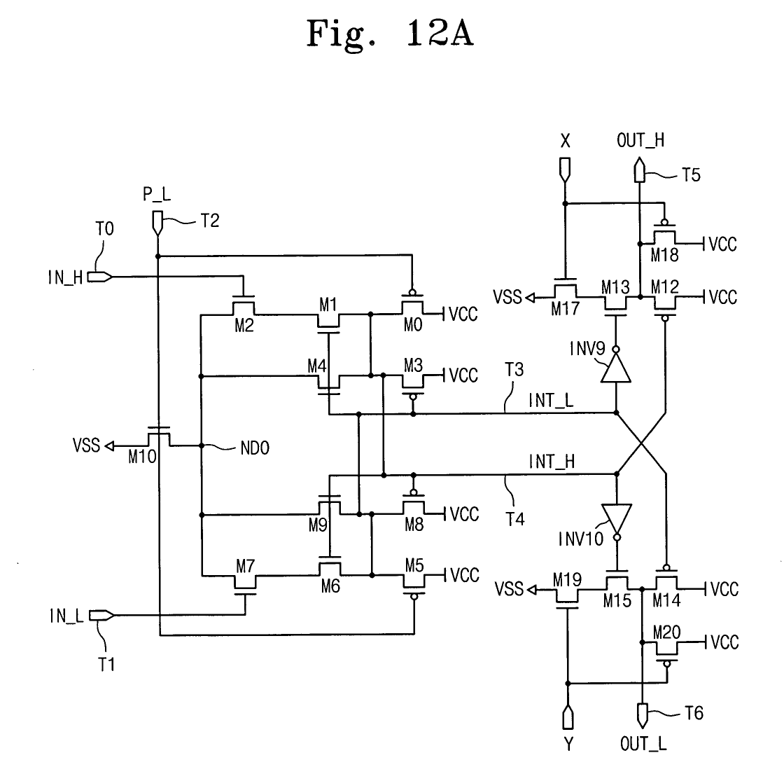

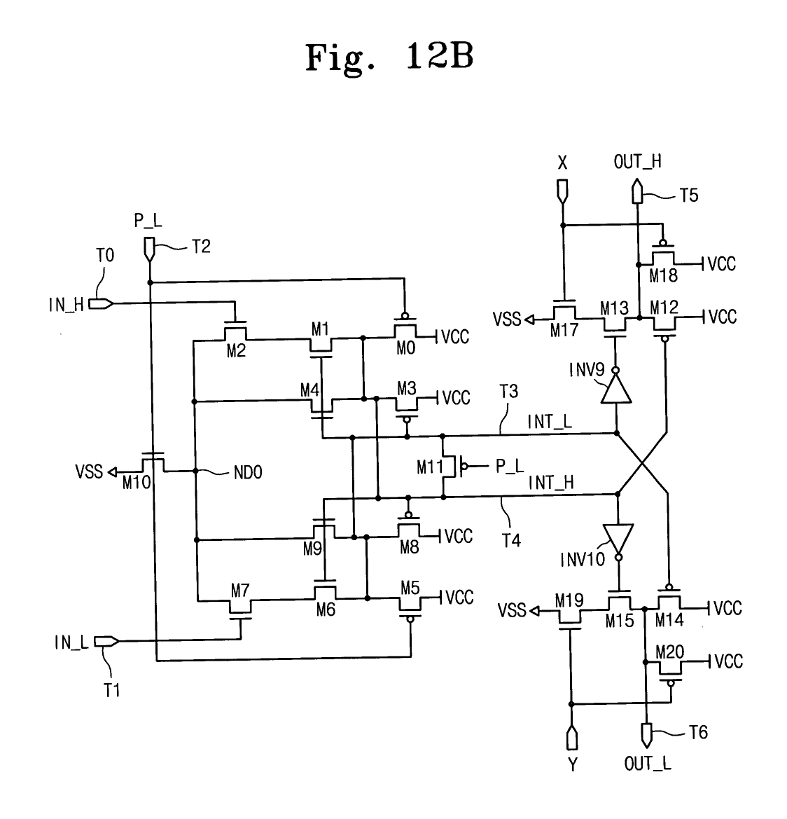

The tri-state buffer 260 in FIGS. 10A and 10B may be modified in various ways. For example, the tri-state buffer 260 may be configured to have various logic functions such as NAND, NOR, etc. FIG. 12A shows the tri-state buffer 260 configured to have a NAND function. In order to realize a NAND function, four transistors M17, M18, M19, and M20 are added in the tri-state buffer 260 in FIG. 10A. The NMOS transistor M17 is connected between an NMOS transistor M13 and a ground voltage VSS, and is controlled by an input signal X. The PMOS transistor M18 is connected between a power supply voltage VCC and a terminal T5, and is controlled by the input signal X. The NMOS transistor M19 is connected between an NMOS transistor M15 and a ground voltage VSS, and is controlled by an input signal Y. The PMOS transistor M20 is connected between a power supply voltage VCC and a terminal T6 and is controlled by the input signal Y. Except for the above-described differences, the sense amplifier and a tri-state buffer in FIG. 12A are identical to those in FIG. 10A, and description thereof is thus omitted.

The sense amplifier 140 in FIG. 12B is identical to that in FIG. 12A except that a PMOS transistor M11 controlled by an active low pulse signal P_L is added as in the embodiment of FIG. 7B. As described above, the PMOS transistor M11 is to speed up a precharge operation for the T3 and T4 terminals.

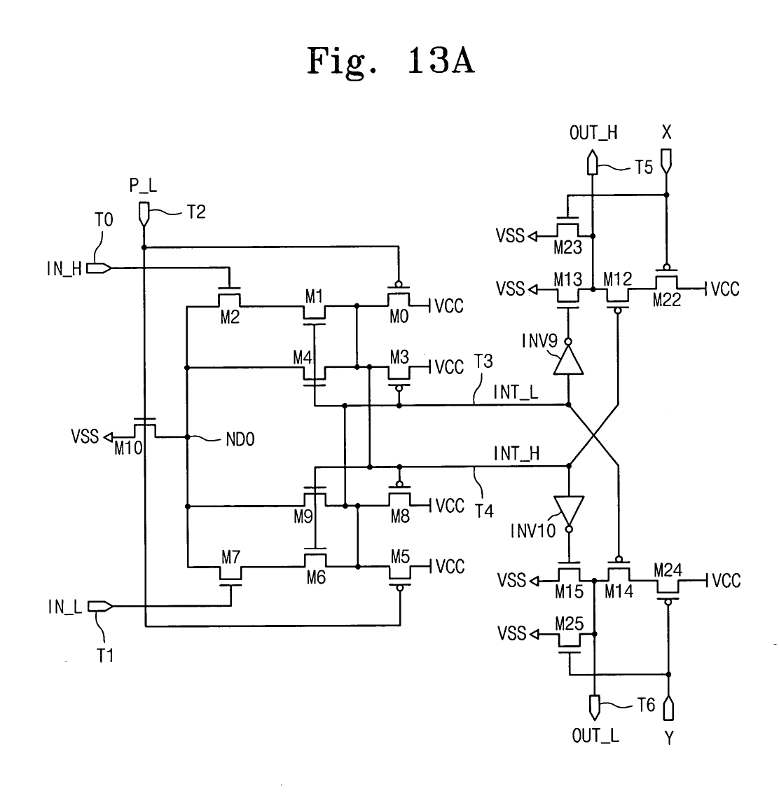

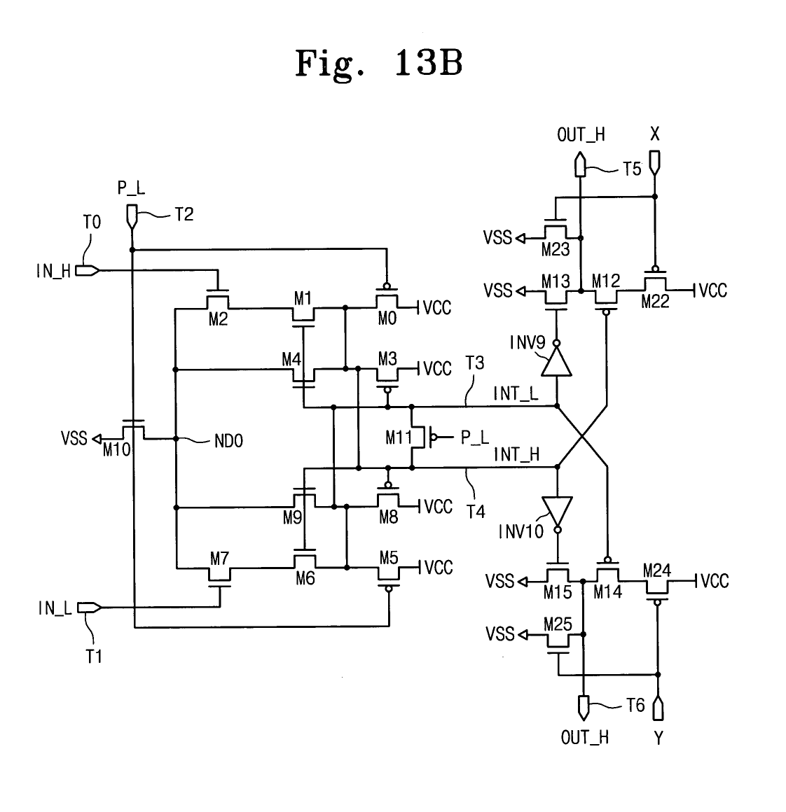

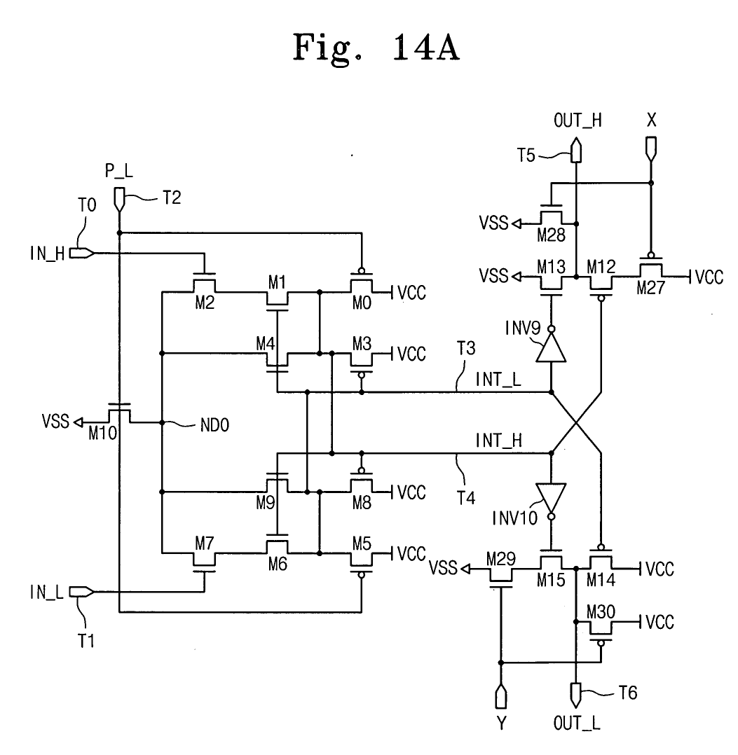

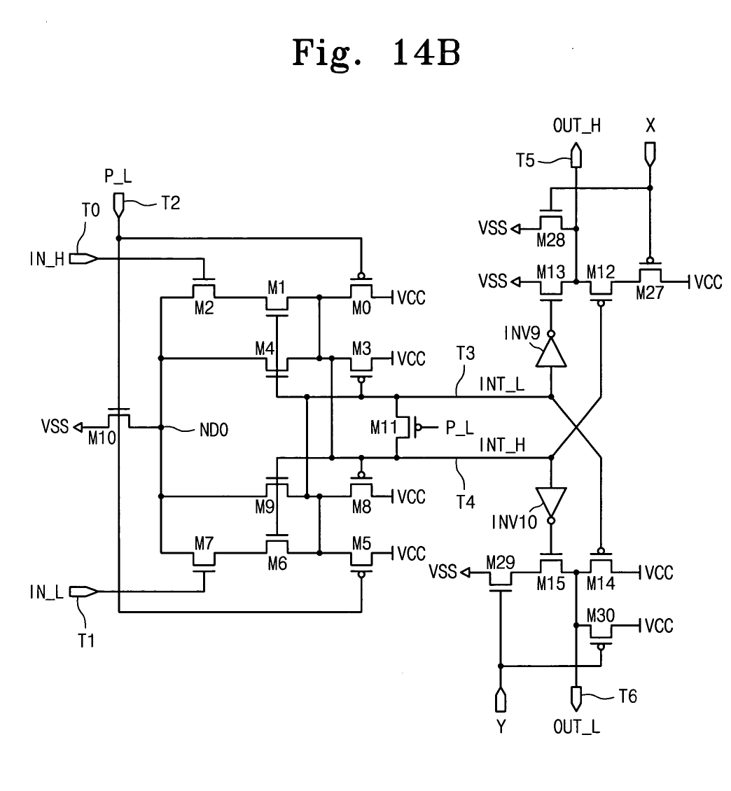

As another embodiment, the tri-state buffer 260 is configured to have a NOR function as illustrated in FIG. 13A. In order to realize a NOR function, four transistors M22, M23, M24, and M25 are added in the tri-state buffer 260 in FIG. 10A. The PMOS transistor M22 is connected between a power supply voltage VCC and a PMOS transistor M12, and is controlled by an input signal X. The NMOS transistor M23 is connected between a terminal T5 and a ground voltage VSS, and is controlled by the input signal X. The PMOS transistor M24 is connected between a power supply voltage VCC and a PMOS transistor M14, and is controlled by an input signal Y. The NMOS transistor M25 is connected between a terminal T6 and a ground voltage VSS, and is controlled by the input signal Y. Except for the above-described differences, the sense amplifier and the tri-state buffer in FIG. 12A are identical to those in FIG. 10A, and description thereof is thus omitted.

The sense amplifier 140 in FIG. 13B is identical to that in FIG. 13A except that a PMOS transistor M11 controlled by an active low pulse signal P_L is added as in the embodiment of FIG. 7B. As described above, the PMOS transistor M11 is to speed up a precharge operation for T3 and T4 terminals.

In yet other embodiments, a tri-state buffer 260 may be configured to have NAND and NOR functions as illustrated in FIG. 14A. In order to realize the NAND and NOR functions, four transistors M27, M28, M29, and M30 are added in the tri-state buffer 260 in FIG. 10A. The PMOS transistor M27 is connected between a power supply voltage VCC and a PMOS transistor M12, and is controlled by an input signal X. The NMOS transistor M28 is connected between a terminal T5 and a ground voltage VSS, and is controlled by the input signal X. The NMOS transistor M29 is connected between an NMOS transistor M15 and a ground voltage VSS, and is controlled by an input signal Y. The PMOS transistor M30 is connected between a power supply voltage VCC and a terminal T6, and is controlled by the input signal Y. Except for the above-described differences, the sense amplifier and a tri-state buffer in FIG. 14A are identical to those in FIG. 10A, and description thereof is thus omitted.

The sense amplifier 140 in FIG. 14B is identical to that in FIG. 14A except that a PMOS transistor M11 controlled by an active low pulse signal P_L is added as in the embodiment of FIG. 7B. As described above, the PMOS transistor M11 is to speed up a precharge operation for T3 and T4 terminals.

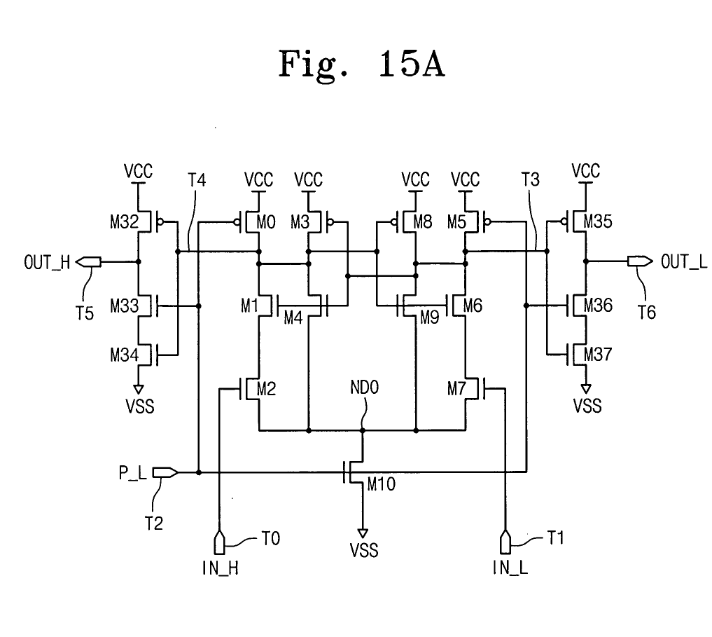

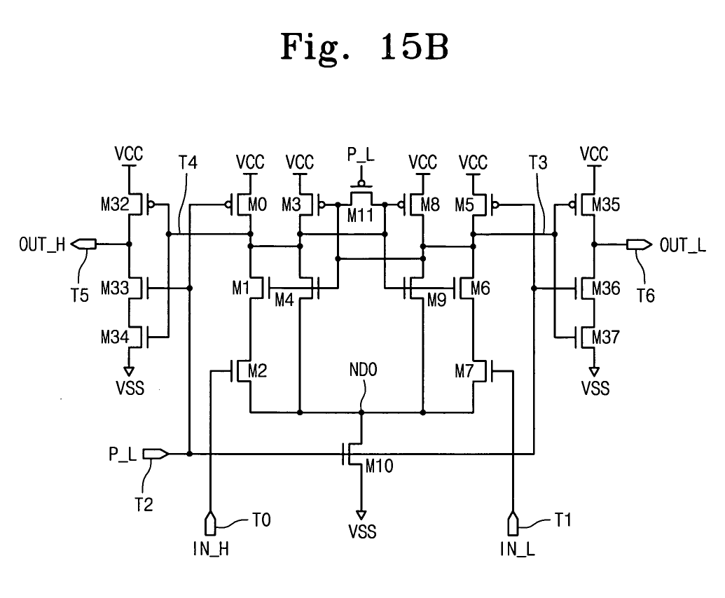

FIG. 15A shows a circuit diagram of a tri-state buffer according to another embodiment of the present invention. As shown, the tri-state buffer 260 comprises six transistors M32, M33, M34, M35, M36, and M37. The PMOS transistor M32 is connected between a power supply voltage VCC and a T5 terminal, and is controlled by a potential of the T4 terminal. The NMOS transistors M33 and M34 are connected in series between the T5 terminal and a ground voltage VSS. A gate of the NMOS transistor M33 is connected to the T2 terminal, and a gate of the NMOS transistor M34 is connected to the T4 terminal. The PMOS transistor M35 is connected between a power supply voltage VCC and a T6 terminal, and is controlled by a potential of the T3 terminal. The NMOS transistors M36 and M37 are connected in series between the T6 terminal and a ground voltage VSS. A gate of the NMOS transistor M36 is connected to the T2 terminal, and a gate of the NMOS transistor M37 is connected to the T3 terminal. Except for the above-described differences, the sense amplifier 140 and a tri-state 260 in FIG. 15A are identical to that in FIG. 10A, and a description thereof is thus omitted.

The sense amplifier 140 in FIG. 15B is identical to that in FIG. 15A except that a PMOS transistor M11 controlled by an active low pulse signal P_L is added as in the embodiment of FIG. 7B. As described above, the PMOS transistor M11 is to speed up a precharge operation for T3 and T4 terminals.

Since output terminals of the SAFF circuits according to the second embodiment float for a shorter time than a time corresponding to a low-level interval of a clock signal CLK (for example, a precharge interval of a sense amplifier as a low-level interval of an active low pulse signal), no latches are required to remove external noise affects. For this reason, it is possible to prevent excessive short circuit current generated in a SAFF circuit.

As discussed above, it is possible to reduce the size chip and power consumption in the SAFF circuit and provide signal persistence, usually afforded by a flip-flop, by use of a sense amplifier. In addition, logic depth may be reduced, and it is possible to improve an operating speed.

The invention has been described using example embodiments. However, it is to be understood that the scope of the invention is not limited to the disclosed embodiment. On the contrary, it is intended to cover various modifications and similar arrangements. The scope of the claims, therefore, should be accorded the broadest interpretation so as to encompass all such modifications and similar arrangements.

What is claimed is:

1. A flip-flop circuit comprising:
a pulse generator for generating a signal pulse in response to one of a first transition and a second transition of a clock signal; and
a sense amplifier for sensing differential input signals to generated sensed differential input signals in response to the signal pulse and for maintaining the sensed differential input signals until receipt of a subsequent signal pulse.

2. The flip-flop circuit of claim 1, wherein the pulse generator generates the signal pulse in synchronization with a low-to-high transition of the clock signal.

3. The flip-flop circuit of claim 1, wherein the pulse generator generates the signal pulse in synchronization with a high-to-low transition of the clock signal.

4. The flip-flop circuit of claim 1, wherein a width of the signal pulse is maintained constant regardless of a frequency variation of the clock signal.

5. The flip-flop circuit of claim 1, wherein the pulse generator includes a NAND gate.

6. The flip-flop circuit of claim 1, wherein the pulse generator includes a NOR gate.

7. The flip-flop circuit of claim 1, wherein the signal pulse transitions from high-to-low and then from low-to-high.

8. The flip-flop circuit of claim 7, wherein the sense amplifier is configured to sense the differential input signals at a rising edge of the signal pulse.

9. The flip-flop circuit of claim 1, wherein the sense amplifier is configured to sense the differential input signals at a rising edge of the signal pulse.

10. The flip-flop circuit of claim 1, wherein the sense amplifier comprises:
a pulse input terminal for receiving the signal pulse;
first and second input terminals for receiving the differential input signals, respectively; and
first and second output terminals for outputting the sensed differential input signals, respectively.

11. The flip-flop circuit of claim 10, wherein the sense amplifier performs a precharge operation from a falling edge of the signal pulse to a rising edge of the signal pulse so that the first and second output terminals are precharged with a voltage.

12. The flip-flop circuit of claim 10, further comprising:
first and second inverters connected to the first and second output terminals, respectively.

13. The flip-flop circuit of claim 10, further comprising:
a PMOS transistor connected between the first and second output terminals and controlled by the signal pulse.

14. A flip-flop circuit comprising:
a pulse generator for generating a signal pulse in response to one of a first transition and a second transition of a clock signal;
a sense amplifier for sensing differential input signals to generate sensed differential input signals in response to the signal pulse and for maintaining the sensed differential input signals until receipt of a subsequent signal pulse; and
a buffer for buffering the sensed differential input signals from the sense amplifier.

15. The flip-flop circuit of claim 14, wherein the pulse generator generates the signal pulse in synchronization with a low-to-high transition of the clock signal.

16. The flip-flop circuit of claim 14, wherein the pulse generator generates the signal pulse in synchronization with a high-to-low transition of the clock signal.

17. The flip-flop circuit of claim 14, wherein a pulse width of the signal pulse is maintained constant regardless of a frequency variation of the clock signal.

18. The flip-flop circuit of claim 14, wherein the sense amplifier comprises:
a pulse input terminal for receiving the signal pulse;
first and second input terminals for receiving the differential input signals, respectively; and
first and second output terminals for outputting the sensed differential input signals, respectively.

19. The flip-flop circuit of claim 18, wherein the sense amplifier performs a precharge operation from a falling edge of the signal pulse to the rising edge of the signal pulse so that the first and second output terminals are precharged with a voltage.

20. The flip-flop circuit of claim 18, wherein the buffer comprises:
a first inverter connected to the first output terminal; and
a second inverter connected to the second output terminal.

21. The flip-flop circuit of claim 20, wherein the buffer further comprises:
a first PMOS transistor having a current path formed between a power supply voltage and a first buffer output terminal and a gate connected to the second output terminal;
a first NMOS transistor having a current path formed between the first buffer output terminal and a ground voltage and a gate connected to an output of the first inverter;
a second PMOS transistor having a current path formed between the power supply voltage and a second buffer output terminal and a gate connected to the first output terminal; and
a second NMOS transistor having a current path formed between the second buffer output terminal and the ground voltage and a gate connected to an output of the second inverter.

22. The flip-flop circuit of claim 21, wherein the buffer further comprises:
a third NMOS transistor having a current path formed between the first NMOS transistor and the ground voltage and a gate connected to receive a first control input signal;
a third PMOS transistor having a current path formed between the power supply voltage and the first buffer output terminal and a gate connected to receive the first control input signal;
a fourth NMOS transistor having a current path formed between the second NMOS transistor and the ground voltage and a gate connected to receive a second control input signal; and
a fourth PMOS transistor having a current path formed between the power supply voltage and the second buffer output terminal and a gate connected to receive the second control input signal.

23. The flip-flop circuit of claim 21, wherein the buffer further comprises:
a third PMOS transistor having a current path formed between the power supply voltage and the first PMOS transistor and a gate connected to receive a first control input signal;
a third NMOS transistor having a current path formed between the first buffer output terminal and the ground voltage and a gate connected to receive the first control input signal;
a fourth NMOS transistor having a current path formed between the second NMOS transistor and the ground voltage and a gate connected to receive a second control input signal; and
a fourth PMOS transistor having a current path formed between the power supply voltage and the second buffer output terminal and a gate connected to receive the second control input signal.

24. The flip-flop circuit of claim 18, further comprising:
a PMOS transistor connected between the first and second output terminals and controlled by the signal pulse.

25. The flip-flop circuit of claim 18, wherein the buffer comprises:
a first PMOS transistor having a current path formed between a power supply voltage and a first buffer output terminal and a gate connected to a second output terminal;
a first NMOS transistor having a drain connected to the first buffer output terminal, a source, and a drain connected to receive the signal pulse;
a second NMOS transistor having a drain connected to the source of the first NMOS transistor, a source grounded, and a gate connected to the second output terminal;
a second PMOS transistor having a current path formed between the power supply voltage and a second buffer output terminal and a gate connected to the first output terminal;
a third NMOS transistor having a drain connected to the second buffer output terminal, a source, and a gate connected to receive the signal pulse; and
a fourth NMOS transistor having a drain connected to the source of the third NMOS transistor, a source grounded, and a gate connected to the first output terminal.

26. An operating method of a sense amplifier-based flip-flop circuit comprising:
generating a signal pulse in response to one of a first transition and a second transition of a clock signal;
precharging outputs of the sense amplifier in response to the signal pulse;
sensing differential input signals in response to the signal pulse; and
maintaining the sensed differential input signals until a subsequent signal pulse.

27. The method of claim 26, wherein the signal pulse is generated in synchronization with a low-to-high transition of the clock signal.

28. The method of claim 26, wherein the signal pulse is generated in synchronization with a high-to-low transition of the clock signal.

29. The method of claim 26, wherein a pulse width of the signal pulse is maintained constant regardless of a frequency variation of the clock signal.

30. The method of claim 26, wherein the signal pulse transitions from high-to-low and then from low-to-high.

31. The method of claim 30, wherein
the precharging step precharges the sense amplifier in response to a falling edge of the signal pulse; and
the sensing step senses the differential input signals in response to a rising edge of the pulse signal.

32. The method of claim 26, wherein
the precharging step precharges the sense amplifier in response to a falling edge of the signal pulse; and
the sensing step senses the differential input signals in response to a rising edge of the pulse signal.

33. The method of claim 26, further comprising:
buffering the sensed differential input signals.
